(19) United States
(12) Patent Application Publication
(10) Pub. No.: US 2023/0215838 A1
(43) Pub. Date: Jul. 6, 2023

(54) Joining and Insulating Power Electronic Semiconductor Components

(71) Applicant: Siemens Aktiengesellschaft, München (DE)

(72) Inventors: Bernd Müller, Falkenberg (DE); Christian Nachtigall-Schellenberg, Potsdam (DE); Jörg Strogies, Berlin (DE); Klaus Wilke, Berlin (DE)

(73) Assignee: Siemens Aktiengesellschaft, München (DE)

(21) Appl. No.: 17/928,318

(22) PCT Filed: May 19, 2021
(86) PCT No.: PCT/EP2021/063280

§ 371 Date: Nov. 29, 2022

(30) Foreign Application Priority Data
May 29, 2020 (DE) 10 2020 206 763.5

(51) Int. Cl. H01L 23/00; H01L 21/56; H01L 23/31

(52) U.S. Cl. CPC H01L 24/92; H01L 24/33; H01L 24/29; H01L 24/32; H01L 24/73; H01L 24/16; H01L 24/81; H01L 24/83; H01L 21/563; H01L 23/3185; H01L 2224/33183; H01L 2224/3303; H01L 2224/29191; H01L 2924/0715; H01L 2224/29291; H01L 2224/29387; H01L 2224/29388; H01L 2224/32225; H01L 2224/73204; H01L 2224/16227; H01L 2224/9211; H01L 2224/81201; H01L 2224/83201; H01L 2224/8184; H01L 2224/83102; H01L 23/585

(57) ABSTRACT

Various embodiments of the teachings herein include a method for joining and insulating a power electronic semiconductor component with contact surfaces to a substrate. In some embodiments, the method includes: preparing the substrate with a metallization defining an installation slot having joining material, wherein the substrate comprises an organic or a ceramic wiring support; arranging an electrically insulating film and the semiconductor component on the substrate, such that the contact surfaces of the semiconductor component facing the substrate are omitted from the film and regions of the semiconductor component exposed by the contact surfaces are insulated at least in part by the film from the substrate and from the contact surfaces; and joining the semiconductor component to the substrate and electrically insulating the semiconductor component at least in part by the film in one step.

### CROSS-REFERENCE TO RELATED APPLICATIONS

This application is a U.S. National Stage Application of International Application No. PCT/EP2021/063280 filed May 19, 2021, which designates the United States of America, and claims priority to DE Application No. 10 2020 206 763.5 filed May 29, 2020, the contents of which are hereby incorporated by reference in their entirety.

### TECHNICAL FIELD

The present disclosure relates to semiconductors. Various embodiments of the teachings herein include methods and/or systems for simultaneous joining and insulating a power electronic semiconductor component on an organic and/or ceramic substrate.

### BACKGROUND

Power electronic semiconductor components in the form of direct-mounted power chips require high-performance encapsulation close to the chip in order to achieve the structural objectives with regard to thermomechanical resistance, electrical insulation and additive moisture resistance. This problem occurs in particular when assembling the chips in a so-called flip-chip orientation (with the chip upper side facing the substrate). The processing of this encapsulation close to the chip is technologically complex and prone to error as a result of material and process fluctuations.

To date, the problem has been solved primarily by the use of a capillary flow underfill for encapsulation close to the chip, the processing being correspondingly complex as well as prone to error.

DE 10 2006 013 853 A1 discloses a power semiconductor element having an insulation adhesive layer and/or an insulation bonding film material, which is arranged between a power semiconductor chip side and a flat conductor material side.

### SUMMARY

The teachings of the present disclosure may allow the joining and insulating of power electronic semiconductor components on a ceramic and/or organic substrate in a simpler and more efficient manner. For example, some embodiments include a method for joining and insulating a power electronic semiconductor component (30) with contact surfaces (34, 35) to a substrate (10), comprising the steps: providing the substrate (10) with a metallization (12) which has an installation slot having joining material (14, 15) and wherein the substrate (10) is an organic or a ceramic wiring support, arranging an electrically insulating film (20) and the semiconductor component (30) on the substrate (10), such that the contact surfaces (34, 35) of the semiconductor component (30) facing the substrate (10) are omitted from the film (20) and regions (35) of the semiconductor component (30) exposed by the contact surfaces (34, 35) are insulated at least in part by the film (20) from the substrate (10) and from the contact surfaces (34, 35), and joining the semiconductor component (30) to the substrate (10) and electrically insulating the semiconductor component (30) at least in part by the film (20) in one step.

In some embodiments, the semiconductor component (30) rests on the joining material (14) and/or the film (20).

In some embodiments, the method further comprises closing a remaining gap (40) between the metallization (12), the film (20) and the semiconductor component (30) by means of an underfill material (25).

In some embodiments, a pressure is exerted on the semiconductor component (30) to join the semiconductor component (30) such that the film (20) is exposed to the pressure at least in part during joining.

In some embodiments, the film (20) electrically insulates the joining material (12) from the regions (35) of the semiconductor component (30) exposed by the contact surfaces (34, 35).

In some embodiments, the film (20) insulates a guard ring region (36) of the semiconductor component (30).

In some embodiments, the film (20) is dimensioned such that, after joining, it protrudes from a gap between the metallization (12) of the substrate (10) and the semiconductor component (30).

In some embodiments, the film (20) has or consists of an elastomer, in particular a silicone elastomer.

In some embodiments, the film (20) comprises a filler, in particular a ceramic filler.

In some embodiments, the film (20) has an adhesive layer.

In some embodiments, the film (20) has a fiber filling, in particular a glass fiber filling.

As another example, some embodiments include a composite of a power electronic semiconductor component (30) with contact surfaces (34, 35) and a substrate (10) with an especially structured metallization (12), wherein the substrate (10) is an organic and/or a ceramic wiring support, wherein the contact surfaces (34, 35) are joined to the metallization (12), having an electrically insulating film (20) which is arranged in such a way that regions of the semiconductor component (30) exposed by the contact surfaces (34, 35) are insulated at least in part by the film (20) from the substrate (10) and from the contact surfaces (34, 35).

In some embodiments, the film (20) protrudes under the semiconductor component (30).

In some embodiments, the film (20) is completely covered by the semiconductor component (30).

In some embodiments, the film (20) is arranged in such a way that a guard ring region of the semiconductor component (30) is electrically insulated from the film.

In some embodiments, there is an underfill material (25), in particular in a gap (40) between the metallization (12), the film (20) and the semiconductor component (30).

### BRIEF DESCRIPTION OF THE DRAWINGS

Hereinafter the teachings of the present disclosure are described and explained in more detail with reference to the exemplary embodiments shown in the figures. The figures show:

FIG. 1 a diagrammatic view of a composite of a power electronic semiconductor component on a substrate incorporating teachings of the present disclosure;

FIG. 2 the composite of FIG. 1 after an underfill process,

FIG. 3 a further embodiment of a composite incorporating teachings of the present disclosure; and

FIG. 4 a further embodiment of a composite incorporating teachings of the present disclosure.

### DETAILED DESCRIPTION

In some embodiments of the teachings herein, a method for joining and insulating a power electronic semiconductor component with contact surfaces on a substrate may include: providing the substrate with a metallization, wherein the substrate has an installation slot with joining material and wherein the substrate is an organic and/or a ceramic wiring support, arranging an electrically insulating film and the semiconductor component on the substrate, such that: the contact surfaces of the semiconductor component facing the substrate are omitted from the film and regions of the semiconductor component exposed by the contact surfaces are insulated at least in part by the film from the substrate and from the contact surfaces, and joining the semiconductor component to the substrate and insulating the semiconductor component at least in part by means of the film in one step.

The metallization of the wiring support is already structured so that the installation slots for the semiconductor components are formed. Furthermore, the structured metallization forms space for possible further components and conductor tracks. Such wiring supports are, for example, printed circuit boards (also PCBs) or metallized and structured ceramic substrates. In this case, the semiconductor component can be designed, for example, as an unhoused semiconductor switch (for example, a bare die) and for this purpose has, for example, three contacts or contact surfaces, thereof, for example, two contact surfaces on the underside of the chip. With its metallization, the substrate provides the electrical connection of the contact surfaces for the semiconductor component. In this case, the installation slot is to be designed correspondingly in accordance with the semiconductor component. The joining material is preferably designed as a sintering paste.

In some embodiments, the joining is a sintering process and is completed by exerting pressure and temperature on the semiconductor component and thus on the joining material and the film. The semiconductor component is pressed onto the film in such a way that the joint is completed under the exertion of pressure and temperature and the film brings about a gap closure as a result of its inherent elasticity. In the joined state, which is to say, for example, in the sintered state, the film is arranged, or clamped, between the substrate and the semiconductor component in such a way that at least partial insulation of the semiconductor component with respect to the substrate and its metallization occurs. In this case, the insulation properties can be controlled advantageously and with regard to the process control very simply by the material properties and by the geometric dimensions of the film.

The film is arranged on the substrate in such a way that the joining material protrudes through the film. The film therefore has recesses at the points at which the joining material is provided. The film is furthermore arranged in such a way that the regions of the semiconductor component exposed by the contact surfaces are at least partially insulated by the film. The film already provides a large part of the insulation required, and thus further insulation can either later be dispensed with completely or the subsequent insulation is significantly simplified by further insulation materials. In this case, the film insulates both the electrically conductive joining material and the semiconductor component and the metallization of the substrate.

In some embodiments, the semiconductor component rests on the joining material and/or the film. It is conceivable for the semiconductor component to rest only on the film or the joining material before joining. As a result of the joining, it is then achieved that the semiconductor component is joined and terminates with the film. It has been shown that it is possible for the semiconductor component to rest on the film and on the joining material and likewise to rest only on the joining material or only on the film and only then comes into contact with the film or with the joining material as a result of the joining process.

In some embodiments, the method comprises the step of closing a remaining gap between the metallization, the film and the semiconductor component by means of an underfill material. This variable combination of prefabricated insulation layers, provided by the film, and the targeted selective application of underfill materials, in particular of capillary flow underfills, enables the respective volume fractions to be designed optimally in terms of design and technology. Technologically, a good adaptability of the individual regions is achieved while maintaining particularly good continuity with subsequent process steps. Preferably, the gap is closed after joining as in particular the capillary flow underfills have a high creeping action and can be introduced into the gap easily. It is also possible to dispense some underfill material at the points to be expected on the film or between the film and the joining material before joining, so that it is already pressed to the correct point.

In some embodiments, a pressure is exerted on the semiconductor component to join the semiconductor component. This is the case, for example, with sintering. In this case, the pressure interacts with the film and the semiconductor component in such a way that the film is at least partially exposed to the pressure during joining between the substrate and the semiconductor component. The pressure thus acts on the film between the substrate and the semiconductor component. In other words, the film can be squeezed by the pressure and thus bring about a gap closure. The film can also perform a flow movement as a result of the pressure. Depending on the film, however, an elastic deformation of the film can also occur, which produces a particularly good seal. In some embodiments, a pressure of 10 MPa to 20 MPa is used during joining.

In some embodiments, the film insulates the joining material from the regions of the semiconductor component exposed by the contact surfaces. In some embodiments, the film also insulates the regions of the metallization exposed by the joint or the joining material.

In some embodiments, the film insulates a guard ring region of the semiconductor. Some semiconductor components have so-called guard rings for improving interference immunity and EMC. These are electrically conductive regions which are arranged as a not necessarily round “ring” at the edge of the semiconductor. Often, it is necessary to insulate them particularly carefully in order not to endanger the valuable properties of the semiconductor. The film, is very well suited for this purpose. It has furthermore been shown that here a film can considerably improve the corrosion properties of the guard ring compared to an underfill.

In some embodiments, the film is dimensioned such that, after joining, the film protrudes from a gap between the metallization of the substrate. In most cases, this can be achieved in that the film has larger dimensions than the chip, which is to say, than the semiconductor component. Furthermore, the film can also be dimensioned such that it is pressed out of the gap by compressing during the joining process. This is the case, in particular, when the film is somewhat higher than the semiconductor component in the unjoined state. In some embodiments, the film can also be dimensioned by its thickness in such a way that a certain squeezing and flowing of the film into remaining gaps occurs during joining. This occurs, in particular, when the film first comes into contact with the chip.

In some embodiments, the film has or consists of an elastomer, in particular a silicone elastomer. It may be advantageous to use such materials for insulation as they combine the required electrical insulation effect with excellent material properties. The film may alternatively comprise or consist of other known electrically insulating plastics.

In some embodiments, the film has a ceramic filler in particular. In addition to the insulation properties of the film, other properties such as heat conduction and coefficient of expansion can also be adapted in this way. Optimized chip-film combinations can thus be produced. Thus, for example, a plastic film with a ceramic filler can be used.

In some embodiments, the film has an adhesive layer. The adhesive layer can be attached to the film on one side or on both sides. In this case, the adhesive layer can be used for fastening the film to the substrate, but the adhesive layer can also be used for fastening the film to the semiconductor component. The adhesive layer thus leads to an increased robustness of the unjoined structure. This facilitates the handling of the unjoined structures. The adhesive layer can also contribute to the design of the joining process as squeezing out of the film can be reduced by the joining material (for example, sintered material), since the film offers a certain resistance.

In some embodiments, the film has a fiber filling, in particular a glass fiber filling. Thus, in particular, the mechanical properties of the film can be adapted to the requirements of the final field of application of a circuit which has the composite. The fiber filling may be a fabric filling. The fabric can thus act as a reinforcement, it being possible for the reinforcement to be adapted to the lateral coefficients of thermal expansion (CTE) accordingly. In particular, the fabrics have been found to be advantageous in comparison with dispersed and non-concatenated filler particles. Films of this type with fiber filling can be purchased, for example, as prepreg. Polysiloxane films can also be purchased with fabric filling.

As another example, some embodiments of the teachings herein include a composite of a power electronic semiconductor component and a substrate. In this case, the power electronic semiconductor component has contact surfaces and the substrate has a metallization. The substrate is an organic and/or a ceramic wiring support.

The metallization may be already structured. In this case, the contact surfaces are joined to the metallization of the substrate, in particular by one or more of the methods described herein, in the region of an installation slot. The composite furthermore comprises an electrically insulating film which is arranged in such a way that regions of the semiconductor component exposed by the contact surfaces are at least partially insulated by the film from the metallization of the substrate and from the contact surfaces. In other words, the film is arranged in such a way that the metallization of the substrate is electrically insulated from the regions of the semiconductor component which are to be insulated.

If pressure is exerted on the semiconductor component during joining, the composite exhibits a permanent elastic deformation of the film or a film deformed by flow processes, depending on the film used. The film thus develops the insulation and sealing effect as a result of the pressure exerted.

In some embodiments, the film protrudes below the semiconductor component. As a result, reliable insulation of the guard ring regions and the direct chip edge is achieved by the film. In addition, an additive underfill can be provided to further protect chip edges.

In some embodiments, the film is completely covered by the semiconductor component. This variant also enables reliable insulation of the guard ring region by the film and furthermore enables the use of a larger proportion of already tested and validated underfills.

In some embodiments, the film is arranged such that a guard ring region of the semiconductor component is insulated from the film. Thus, the particular requirements of the guard ring region with regard to insulation quality can be met by the film.

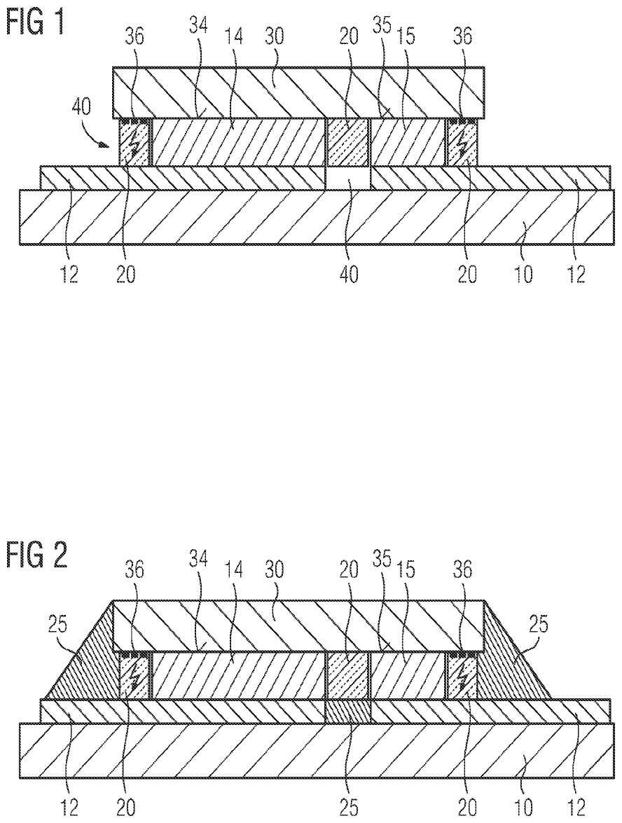

FIG. 1 shows an exemplary embodiment of the teachings herein including an already joined composite of a power electronic semiconductor component 30 with contact surfaces 34, 35 and a substrate 10 with a metallization 12. The contact surfaces 34, 35 are already joined to the metallization 12 via a respectively associated joining material 14, 15. An electrically insulating film 20 is arranged in such a way that regions of the semiconductor component 30 exposed by the contact surfaces 34, 35 are at least partially insulated by the film 20 from the substrate 10, from the joining material 14, 15 and from the contact surfaces 34, 35. The joining material 14, 15 shown is a sintered material. In this case, the power electronic semiconductor component 30 has a guard ring in a guard ring region 36. In this case, the guard ring region 36 is electrically insulated by the film 20 from the joining material 14, 15, and from the metallization 12. A gap 40 remains as the film 20 does not protrude below the semiconductor component 30. The embodiments shown in FIG. 1-4 are also applicable to semiconductor components which do not have a guard ring.

FIG. 2 shows the composite known from FIG. 1, the gap 40 being filled by an underfill material 25. The underfill material 25 thus ensures complete insulation and additionally seals off remaining regions. The so-called “gate trench” between metallization can also be filled by the underfill material.

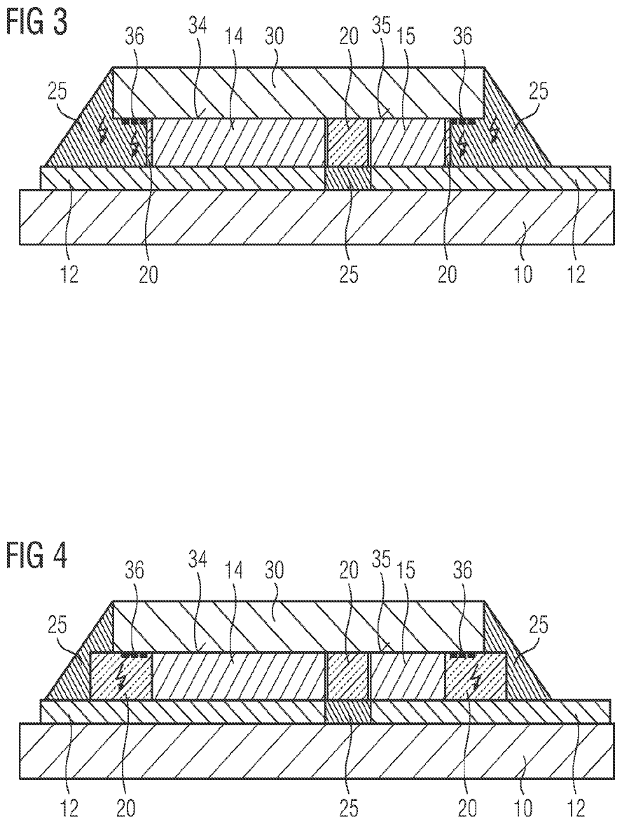

FIG. 3 shows an embodiment of the teachings herein in which the film 20 is used as a direct release layer to the porous sintered layer, which is to say, the joining material 14, 15. The guard ring region 36 and the chip edge are furthermore insulated via an underfill 25 and thermomechanically stabilized. This advantageously has the consequence that the insulation of the guard ring region 36 and the chip edge can be carried out with a tested underfill 25. The influence of the already tested underfill on the thermomechanical behavior is accordingly low.

FIG. 4 shows a composite incorporating teachings of the present disclosure in which the film 20 protrudes from below the chip. Thus, a gap 40 cannot form at the edges of the semiconductor component 30, as shown in FIG. 1, but only below the semiconductor component 30 or in the plane of the metallization 12 (also referred to as a “gate trench”). This embodiment enables reliable insulation of the guard ring regions 36 and the immediate chip edge with a film, in particular a pretested film 20. Depending on the field of application, this can lead to considerable advantages with regard to preventing guard ring corrosion.

With regard to the embodiments shown in the figures, the present solution offers a hybrid encapsulation close to the chip by a film 20 and, if required, supplemented by an underfill material 25. In this case, a combination of capillary flow underfill and compressed elastic films 20 applied during sintering can be used. The films 20 can be cut out in accordance with the chip and sintering depot contours and correspondingly prefabricated.

This variable approach makes it possible to combine the advantages with regard to the connectivity to the conventional encapsulation exclusively by using the Capillary Flow Underfill (with regard to the already understood insulation and thermomechanical properties) with the advantages of the prefabricated films/prepregs with regard to freedom from defects, better insulation properties and process simplifications. Constructively, in this approach, the respective proportion of film 20 and underfill 25 can be varied correspondingly in the chip gap 40 and encapsulation around the chips (semiconductor components 30). A major advantage of the solution is furthermore the retention of the geometric features to the outside, which enables a simple drop-in implementation in existing process sequences.

In summary, some embodiments include a method for joining and insulating a power electronic semiconductor component (30) on a substrate (10). In order to design the joining and insulating of power electronic semiconductor components in a simpler and more efficient manner, the methods may include: providing the substrate (10) with a metallization (12) which has an installation slot having joining material (14, 15), arranging an electrically insulating film (20) and the semiconductor component (30) on the substrate (10), such that the contact surfaces (34, 35) of the semiconductor component (30) facing the substrate (10) are omitted from the film (20) and regions (35) of the semiconductor component (30) exposed by the contact surfaces (34, 35) are insulated at least in part by the film (20) from the substrate (10) and from the contact surfaces (34, 35), and joining the semiconductor component (30) to the substrate (10) and electrically insulating the semiconductor component (30) at least in part by the film (20) in one step. The invention furthermore relates to a joined composite of a power electronic semiconductor component (30) and a substrate (10).

### LIST OF REFERENCE CHARACTERS

10 Substrate
12 Metallization
14, 15 Joining material
20 Electrically insulating film
25 Underfill material
30 Electronic semiconductor component
34, 35 Contact surfaces of the semiconductor component
36 Guard ring region
40 Gap

What is claimed is:

1. A method for joining and insulating a power electronic semiconductor component with contact surfaces to a substrate, the method comprising:
preparing the substrate with a metallization defining an installation slot having joining material, wherein the substrate comprises an organic or a ceramic wiring support;
arranging an electrically insulating film and the semiconductor component on the substrate, such that
the contact surfaces of the semiconductor component facing the substrate are omitted from the film and
regions of the semiconductor component exposed by the contact surfaces are insulated at least in part by the film from the substrate and from the contact surfaces; and
joining the semiconductor component to the substrate and electrically insulating the semiconductor component at least in part by the film in one step.

2. The method as claimed in claim 1, wherein the semiconductor component contacts the joining material and/or the film.

3. The method as claimed in claim 1, further comprising:
closing a remaining gap between the metallization, the film, and the semiconductor component using an underfill material.

4. The method as claimed in claim 1, further comprising exerting pressure on the semiconductor component to join the semiconductor component such that the film is exposed to the pressure at least in part during joining.

5. The method as claimed in claim 1, wherein the film electrically insulates the joining material from the regions of the semiconductor component exposed by the contact surfaces.

6. The method as claimed in claim 1, wherein the film insulates a guard ring region of the semiconductor component.

7. The method as claimed in claim 1, wherein the film, after joining, protrudes from a gap between the metallization of the substrate and the semiconductor component.

8. The method as claimed in claim 1, wherein the film comprises a silicone elastomer.

9. The method as claimed in claim 1, wherein the film comprises a ceramic filler.

10. The method as claimed in claim 1, wherein the film comprises an adhesive layer.

11. The method as claimed in claim 1, wherein the film comprises a glass fiber filling.

12. A composite comprising:
a power electronic semiconductor component with contact surfaces;
a substrate with a structured metallization;
wherein the substrate comprises an organic and/or a ceramic wiring support;
wherein the contact surfaces are joined to the metallization;
an electrically insulating film arranged in such a way that regions of the semiconductor component exposed by the contact surfaces are insulated at least in part by the film from the substrate and from the contact surfaces.

13. The composite as claimed in claim 12, wherein the film protrudes under the semiconductor component.

14. The composite as claimed in claim claim 12, wherein the film is completely covered by the semiconductor component.

15. The composite as claimed in claim 12, wherein the film is arranged in such a way that a guard ring region of the semiconductor component is electrically insulated from the film.

16. The composite as claimed in claim 12, further comprising an underfill material in a gap between the metallization, the film, and the semiconductor component.
